(19) United States
(12) Patent Application Publication
(10) Pub. No.: US 2024/0315119 A1
(43) Pub. Date: Sep. 19, 2024

(54) DISPLAY PANEL AND DISPLAY APPARATUS

(71) Applicants: Hefei Visionox Technology Co., Ltd., Hefei (CN); Visionox Technology Inc., Suzhou (CN)

(72) Inventors: Yuan YAO, Hefei (CN); Chung-Chun LEE, Hefei (CN); Mingxing LIU, Hefei (CN); Xiaoxi SUN, Hefei (CN); Zhengkui DONG, Hefei (CN); Zihan WANG, Hefei (CN); Xiaojuan XUE, Hefei (CN); Xuejing ZHU, Hefei (CN); Liusong NI, Hefei (CN); Zengqiang XIA, Hefei (CN)

(73) Assignees: Hefei Visionox Technology Co., Ltd., Hefei (CN); Visionox Technology Inc., Suzhou (CN)

(21) Appl. No.: 18/664,853

(22) Filed: May 15, 2024

Related U.S. Application Data
(63) Continuation of application No. PCT/CN2024/081633, filed on Mar. 14, 2024.

(30) Foreign Application Priority Data
Mar. 15, 2023 (CN) 202310269378.0
Jun. 30, 2023 (CN) 202310813224.3

(51) Int. Cl. H10K 59/80; H10K 59/122

(52) U.S. Cl. CPC H10K 59/8792; H10K 59/122

(57) ABSTRACT

A display panel and a display apparatus, and the display panel includes an array base plate, as well as an isolation structure, a light-emitting layer, and a light filtering layer formed in sequence on the array base plate. The isolation structure is formed on a side of the array base plate and defines a plurality of isolation openings; the light-emitting layer includes a plurality of light-emitting units arranged at intervals, the light-emitting unit is arranged in the isolation opening and includes a first electrode, a light-emitting functional layer, and a second electrode, the first electrode is formed on a side of the array base plate, the light-emitting functional layer is formed on a side of the first electrode away from the array base plate, the second electrode is formed on a side of the light-emitting functional layer away from the array base plate.

### CROSS-REFERENCE TO RELATED APPLICATION

The present application is a continuation application of International Application No. PCT/CN2024/081633, filed on Mar. 14, 2024, which claims priority to Chinese Patent Application No. 202310269378.0 filed on Mar. 15, 2023, and titled “DISPLAY PANEL AND DISPLAY APPARATUS”, and Chinese Patent Application No. 202310813224.3 filed on Jun. 30, 2023, and titled “DISPLAY PANEL AND DISPLAY APPARATUS”, all of which are incorporated herein by reference in their entireties.

### TECHNICAL FIELD

The present application relates to the field of display technology, and particularly to a display panel and a display apparatus.

### BACKGROUND

The AMOLED display panel has advantages such as wide color gamut, high contrast and various forms, thus the AMOLED display panel has gradually become the mainstream of the display panel used by mobile phone terminals, and has been widely favored by users. However, in current display devices, the reflectivity of the display panel is relatively high, resulting in poor performance of the display panel, thereby affecting the user experience.

### SUMMARY

Embodiments of the present application provide a display panel and a display apparatus, which can reduce the reflectivity of the display panel.

Embodiments of a first aspect of the present application provide a display panel, including:
an array base plate;
an isolation structure formed on a side of the array base plate and defining a plurality of isolation openings;
a light-emitting layer including a plurality of light-emitting units arranged at intervals, wherein the light-emitting unit is arranged in the isolation opening and includes a first electrode, a light-emitting functional layer, and a second electrode, the first electrode is formed on a side of the array base plate, the light-emitting functional layer is formed on a side of the first electrode away from the array base plate, the second electrode is formed on a side of the light-emitting functional layer away from the array base plate, and adjacent light-emitting units are independent from each other; and
a light filtering layer formed on a side of the light-emitting layer away from the array base plate and including light filtering functional portions, wherein the light filtering functional portion is located on a side of the light-emitting unit away from the array base plate and extends to a side of the isolation structure away from the array base plate.

Embodiments of a second aspect of the present application further provide a display panel, including:
an array base plate;
an isolation structure formed on a side of the array base plate and defining a plurality of isolation openings;
a light-emitting layer including a plurality of light-emitting units arranged at intervals, wherein the light-emitting unit is arranged in the isolation opening and includes a first electrode, a light-emitting functional layer, and a second electrode, the first electrode is formed on a side of the array base plate, the light-emitting functional layer is formed on a side of the first electrode away from the array base plate, the second electrode is formed on a side of the light-emitting functional layer away from the array base plate, and adjacent light-emitting units are independent from each other;
an encapsulation layer formed on a side of the light-emitting layer away from the array base plate, wherein the encapsulation layer includes a first encapsulation layer, a second encapsulation layer, and a third encapsulation layer stacked along a direction away from the array base plate; and
a light filtering layer formed between the first encapsulation layer and the second encapsulation layer and including light filtering functional portions, wherein the light filtering functional portion extends to a side of the isolation structure away from the array base plate.

Embodiments of a third aspect of the present application further provide a display apparatus including the display panel according to the first aspect or the second aspect of the present application.

The present application provides the display panel including the array base plate, the isolation structure, the light-emitting layer, and the light filtering layer. The light filtering layer is formed on a side of the light-emitting layer away from the array base plate and includes the light filtering functional portions. The light filtering functional portion may filter the light entering the display panel from the outside, so that the amount of the light entering the display panel is reduced, the amount of the light reflected by the internal structure of the display panel when the light enters the display panel is reduced, and thus the diverged amount of the light reflected by the internal structure of the display panel can be reduced, thereby increasing the contrast of the display panel. Specifically, an orthographic projection of the light filtering functional portion on the array base plate covers at least a part of an orthographic projection of the isolation structure on the array base plate, so that the amount of the external light entering a side surface of the isolation structure away from the array base plate is reduced by covering the isolation structure with the light filtering functional portions. The light towards the isolation structure first enters a part of the light filtering functional portion opposite to the isolation structure, the light of a color different from the color of the light filtering functional portion is filtered out by the light filtering functional portion, and the light entering the light filtering functional portion is refracted or scattered, so that the amount of the light entering the side surface of the isolation structure away from the array base plate is reduced greatly, thereby reducing the amount of the light reflected by the isolation structure, which is helpful to increase the contrast of the display panel. Meanwhile, a light transmittance of the light filtering layer is high, so that the light-emitting rate of the display panel can be ensured while the contrast of the display panel is increased, thereby ensuring low power consumption of the display panel.

### BRIEF DESCRIPTION OF THE DRAWINGS

FIG. 1 is a top view of a display panel according to embodiments of the present application;

FIG. 2 is a schematic cross-sectional view of a display panel according to embodiments of the present application;

FIG. 3 is a schematic cross-sectional view of another display panel according to embodiments of the present application;

FIG. 4 is a schematic cross-sectional view of yet another display panel according to embodiments of the present application;

FIG. 5 is a schematic cross-sectional view of yet another display panel according to embodiments of the present application;

FIG. 6 is a schematic cross-sectional view of yet another display panel according to embodiments of the present application;

FIG. 7 is a schematic cross-sectional view of yet another display panel according to embodiments of the present application;

FIG. 8 is a schematic cross-sectional view of yet another display panel according to embodiments of the present application;

FIG. 9 is a schematic cross-sectional view of yet another display panel according to embodiments of the present application;

FIG. 10 is a schematic cross-sectional view of yet another display panel according to embodiments of the present application;

FIG. 11 is a schematic cross-sectional view of yet another display panel according to embodiments of the present application;

FIG. 12 is a schematic cross-sectional view of yet another display panel according to embodiments of the present application;

FIG. 13 is a schematic structural view of a display apparatus according to embodiments of the present application.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely to provide a better understanding of the present application by illustrating the examples of the present application.

The inventors have found that in current display devices, the reflectivity of the display panel is relatively high, so that the performance of the display panel (such as the contrast and dark state uniformity of the display) is affected, resulting in poor user experience. Based on the study of the above problem, the inventors have provided a display panel and a display apparatus to improve the performance of the display panel.

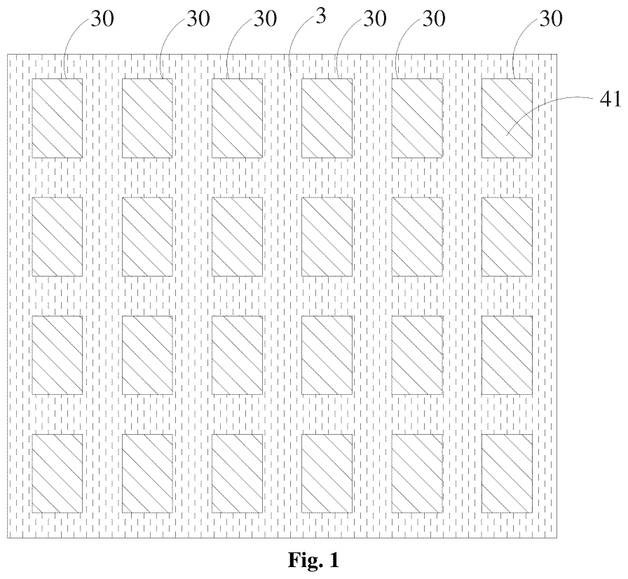

For a better understanding of the present application, a display panel and a display apparatus according to embodiments of the present application will be described in detail below with reference to FIG. 1 to FIG. 13.

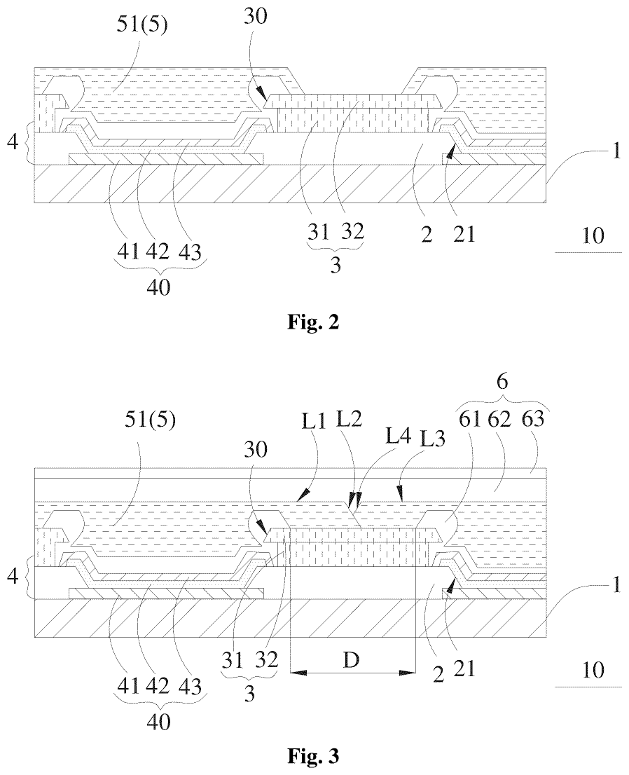

Referring to FIG. 1 and FIG. 2, the embodiments of the present application provide a display panel 10 including an array base plate 1, an isolation structure 3, a light-emitting layer 4, and a light filtering layer 5. The isolation structure 3 is formed on a side of the array base plate 1 and defines a plurality of isolation openings 30. The light-emitting layer 4 includes a plurality of light-emitting units 40 arranged at intervals, the light-emitting unit 40 is arranged in the isolation opening 30 and includes a first electrode 41, a light-emitting functional layer 42, and a second electrode 43, the first electrode 41 is formed on a side of the array base plate 1, the light-emitting functional layer 42 is formed on a side of the first electrode 41 away from the array base plate 1, the second electrode 43 is formed on a side of the light-emitting functional layer 42 away from the array base plate 1, and adjacent light-emitting units 40 are independent from each other. The light filtering layer 5 is formed on a side of the light-emitting layer 4 away from the array base plate 1 and includes light filtering functional portions 51, the light filtering functional portion 51 is located on a side of the light-emitting unit 40 away from the array base plate 1 and extends to a side of the isolation structure 31 away from the array base plate 1.

Specifically, an orthographic projection of the isolation structures 3 on the array base plate 1 may be a grid-like shape.

The present application provides the display panel including the array base plate 1, the isolation structure 3, the light-emitting layer 4, and the light filtering layer 5. The light filtering layer 5 is formed on a side of the light-emitting layer 4 away from the array base plate 1 and includes the light filtering functional portions 51. The light filtering functional portion 51 can filter the light entering the display panel 10 from the outside, so that the amount of the light entering the display panel is reduced, the amount of the light reflected by the internal structure of the display panel 10 when the light enters the display panel 10 is reduced, and thus the diverged amount of the light reflected by the internal structure of the display panel 10 can be reduced, thereby increasing the contrast of the display panel 10. Specifically, an orthographic projection of the light filtering functional portion 51 on the array base plate 1 covers at least a part of an orthographic projection of the isolation structure 3 on the array base plate 1, so that the amount of the external light entering a side surface of the isolation structure 3 away from the array base plate 1 is reduced by covering the isolation structure 3 with the light filtering functional portions 51. Light towards the isolation structure 3 first enters a part of the light filtering functional portion 51 opposite to the isolation structure 3, light of a color different from a color of the light filtering functional portion 51 is filtered out by the light filtering functional portion 51, and the light entering the light filtering functional portion 51 is refracted or scattered, so that the amount of the light entering the side surface of the isolation structure 3 away from the array base plate 1 is reduced greatly, thereby reducing the amount of the light reflected by the isolation structure 3, which is helpful to increase the contrast of the display panel 10. Meanwhile, the light transmittance of the light filtering layer 5 is high, so that the light-emitting rate of the display panel 10 can be ensured while the contrast of the display panel 10 is increased, thereby ensuring low power consumption of the display panel 10.

In the above implementation, an orthographic projection of the light filtering functional portion 51 on the array base plate 1 covers an orthographic projection of the light-emitting unit 40 on the array base plate 1.

In the above display panel 10 according to the present application, by arranging the light filtering layer 5 on a side of the light-emitting unit 40 away from the array base plate 1, light-emitting purity of the light-emitting unit 40 can be increased and the display effect can be improved.

In a feasible implementation, the isolation structure 3 includes a first layer 31 and a second layer 32 stacked along a direction away from the array base plate 1, and an orthographic projection of the first layer 31 on the array base plate 1 is within an orthographic projection of the second layer 32 on the array base plate 1.

In the above implementation, the isolation structure 3 is formed on a side of the array base plate 1, the isolation structure 3 includes the first layer 31 and the second layer 32 stacked along the direction away from the array base plate 1, and the orthographic projection of the first layer 31 on the array base plate 1 is within the orthographic projection of the second layer 32 on the array base plate 1, so that a stepped portion is formed between the second layer 32 and the first layer 31, the second electrode 43 and the light-emitting functional layer 42 in the light-emitting layer 4 are separated at the stepped portion by the stepped portion. Therefore, adjacent light-emitting units 40 are independent from each other, and each light-emitting unit 40 is driven individually, which is helpful to achieve the goal of reducing the power consumption of the display panel 10. Meanwhile, the display panel in the present application is provided with the light filtering layer 5 to filter the light, and a polarizer structure is not provided. Therefore, compared to a conventional display panel provided with a polarizer, the light transmittance of the light filtering layer 5 is higher than a light transmittance of the polarizer, so that the light-emitting rate of the display panel 10 can be ensured while the contrast of the display panel 10 is increased, thereby ensuring low power consumption of the display panel 10.

In a feasible implementation, the display panel further includes a pixel definition layer 2 formed on a side of the array base plate 1 and including a plurality of pixel openings 21. An orthographic projection of the pixel opening 21 on the array base plate 1 coincides with an orthographic projection of the isolation opening 30 on the array base plate 1. The isolation structures 3 are arranged on a side of the pixel definition layer 2 away from the array base plate 1, and an orthographic projection of the isolation structure 3 on the pixel definition layer 2 is located between adjacent pixel openings 21. In other embodiments, the isolation structure 3 may also be arranged directly on a side of the array base plate 1, which is not specifically limited.

In the above implementation, the orthographic projection of the isolation structure 3 on the pixel definition layer 2 is located between adjacent pixel openings 21, so that a problem that the isolation structure 3 blocks the light emitted by the light-emitting unit 40 within the pixel opening 21 (in particular the large-angle light emitted by the light-emitting units 40) can be reduced. Therefore, the brightness of the display panel can be increased, and the power consumption can be further reduced.

In the above display panel 10 according to the present application, by arranging the isolation structure 3 between adjacent pixel openings 21, the light-emitting functional layers 42 within adjacent pixel openings 21 may be disconnected at the isolation structure 3, so that the probability of mutual crosstalk between adjacent light-emitting units 40 can be reduced, which is helpful to further improve the display effect.

In a feasible implementation, a material of the isolation structure 3 is metal, and a material of the pixel-defining layer 2 is an inorganic material.

In the above implementation, the material of the isolation structure 3 is metal, so that the second electrodes 43 between the adjacent light-emitting units 40 may be electrically connected, so as to reduce the number of power supply lines of the second electrodes 43 within the display panel 10, thereby simplifying the wiring within the display panel 10 and reducing manufacturing cost. Meanwhile, the isolation structure 3 is arranged on a side of the pixel definition layer 2 away from the array base plate, and under a condition that the light-emitting units 40 of various colors are manufactured, respective film layers of light-emitting units 40 of one color are formed first on the whole surface, then the light-emitting units 40 of the one color are formed at designated pixel openings 21 by etching, and the pixel openings 21 configured to form light-emitting units 40 of other colors are exposed. Manufacturing of the light-emitting units 40 of different colors is performed in different steps, and during the above manufacturing process, it is not necessary to use a mask plate, and it is not necessary to provide a support pillar on a side of the pixel definition layer 2 away from the array base plate 1, so that the manufacturing cost can be saved. The isolation structure 3 may be made of a dark material, so as to have a light blocking effect, thereby reducing the probability of lateral crosstalk between adjacent light-emitting units 40. Along a thickness direction of the display panel, the light below the isolation structure 3 is blocked to prevent the light from being emitted from the light-emitting surface. The light below the isolation structure 3 specifically includes scattered light in film layers within the pixel definition layer 2 and the array base plate 1. Under this condition, a light-transmitting inorganic material may be used in the pixel definition layer 2 to further reduce the cost of the material.

In a feasible implementation, the orthographic projection of the light filtering functional portion 51 on the array base plate 1 covers at least a part of the orthographic projection of the isolation structure 3 on the array base plate 1, so that a part of light towards the isolation structure 3 can be filtered by the light filtering functional portions 51 to reduce the amount of light reflected by the isolation structure 3.

In a feasible implementation, as shown in FIG. 3, the orthographic projection of the light filtering functional portion 51 on the array base plate 1 covers the orthographic projection of the isolation structure 3 on the array base plate 1.

Specifically, the isolation structure 3 includes a first layer 31 and a second layer 32 stacked along a direction away from the array base plate 1, an orthographic projection of the first layer 31 on the array base plate 1 is located within an orthographic projection of the second layer 32 on the array base plate 1, orthographic projections of adjacent light filtering functional portions 51 on the array base plate 1 are overlapped to form an overlapped region, and an orthographic projection of the overlapped region on the array base plate 1 covers a part of the orthographic projection of the second layer 32 on the array base plate 1, so that the orthographic projection of the light filtering functional portion 51 on the array base plate 1 covers the orthographic projection of the isolation structure 3 on the array base plate 1. Or, the orthographic projection of the light filtering functional portion 51 on the array base plate 1 covers the orthographic projection of the isolation structure 3 on the array base plate 1, and orthographic projections of adjacent light filtering functional portions 51 on the array base plate 1 are staggered.

In the above implementation, under a condition that a material (such as metal) reflecting light easily is used in the isolation structure 3, the amount of the external light entering the side surface of the isolation structure 3 away from the array base plate 1 can be reduced by covering the isolation structure 3 with the light filtering functional portions 51. Specifically, light towards the isolation structure 3 first enters a part of the light filtering functional portion 51 opposite to the isolation structure 3, light of a color different from the color of the light filtering functional portion 51 is filtered out by the light filtering functional portion 51, and the light entering the light filtering functional portion 51 is refracted or scattered, so that the amount of the light entering the side surface of the isolation structure 3 away from the array base plate 1 is reduced greatly, thereby reducing the amount of the light reflected by the isolation structure 3, which is helpful to increase the contrast of the display panel 10.

In one possible implementation, as shown in FIG. 3, orthographic projections of adjacent light filtering functional portions 51 on the array base plate 1 are overlapped to form an overlapped region, and an orthographic projection of the overlapped region on the array base plate 1 covers an orthographic projection of a center of the second layer 32 along an arrangement direction of the adjacent light filtering functional portions 51 on the array base plate 1.

In the above implementation, the isolation structure 3 is covered by the light filtering functional portions 51 located on two sides of the isolation structure 3, so that it can be ensured that the light-emitting units 40 on two sides of the isolation structure 3 are well covered by the light filtering functional portions 51 located on two sides of the isolation structure 3, and the light emitted by the light-emitting units 40 emits out after filtered by the light filtering functional portions 51, which is helpful to ensure the light-emitting purity of the light-emitting units 40. Meanwhile, the orthographic projection of the overlapped region on the array base plate 1 covers the orthographic projection of the center of the second layer 32 along the arrangement direction of the adjacent light filtering functional portions 51 on the array base plate 1, so that the coverage areas of different filter functions 51 on the isolation structure 3 may be similar and relatively large. Compared to the solution in which one light filtering functional portion 51 has a smaller coverage area that only covers the edge of the isolation structure 3 and the other light filtering functional portion 51 has a relatively large coverage area, the accuracy of manufacturing each light filtering functional portion 51 in the manufacturing process in the present application is better controlled, which is helpful to improve manufacturing yield.

Specifically, in the overlapped region formed by overlapping the orthographic projections of adjacent light filtering functional portions 51 on the array base plate 1, one of the light filtering functional portions 51 is gradually thinned along an edge region, and in a cross section of the light filtering functional portion 51 along a thickness direction of the array base plate 1, a side edge of the light filtering functional portion 51 away from the array base plate 1 may include a first edge line L1 parallel to the array base plate and a second edge line L2 connected to the first edge line L1. The second edge line L2 may be a straight line and arranged obliquely relative to the plane where the array base plate 1 is located, or may be an arc line, which is not particularly limited in the present application. An edge region of the other light filtering functional portion 51 may cover the edge region of the above light filtering functional portion 51. Specifically, in a cross section of the other light filtering functional portion 51 along the thickness direction of the array base plate 1, a side edge of the light filtering functional portion 51 away from the array base plate 1 may include a third edge line L3 parallel to the array base plate and a fourth edge line L4 connected to the third edge line L3. The fourth edge line L4 may be a straight line and arranged obliquely relative to the plane where the array base plate 1 is located, or may be an arc line, which is not particularly limited in the present application. In a cross section of the light filtering layer along the thickness direction of the array base plate 1, and in two adjacent light filtering functional portions 51, the fourth edge line L4 may be in contact with the second edge line L2, so that a surface of the overlapped region away from the array base plate 1 is lower than surfaces of other regions away from the array base plate 1.

In a feasible implementation, as shown in FIG. 3, the display panel 10 further includes an encapsulation layer 6 formed on a side of the light-emitting layer 4 away from the array base plate 1, the encapsulation layer 6 includes a first encapsulation layer 61, a second encapsulation layer 62, and a third encapsulation layer 63 stacked along a direction away from the array base plate, and the light filtering layer 5 is arranged in the encapsulation layer 6, or the light filtering layer 5 is arranged on a side of the encapsulation layer 6 away from the array base plate 1 and is arranged adjacent to the encapsulation layer 6.

In the above implementation, the light filtering layer 5 is arranged in the encapsulation layer 6 or on a side of the encapsulation layer 6 away from the array base plate 1, so that the first encapsulation layer 61 is in contact with the light-emitting unit 40, thereby ensuring an encapsulation effect of the encapsulation layer 6.

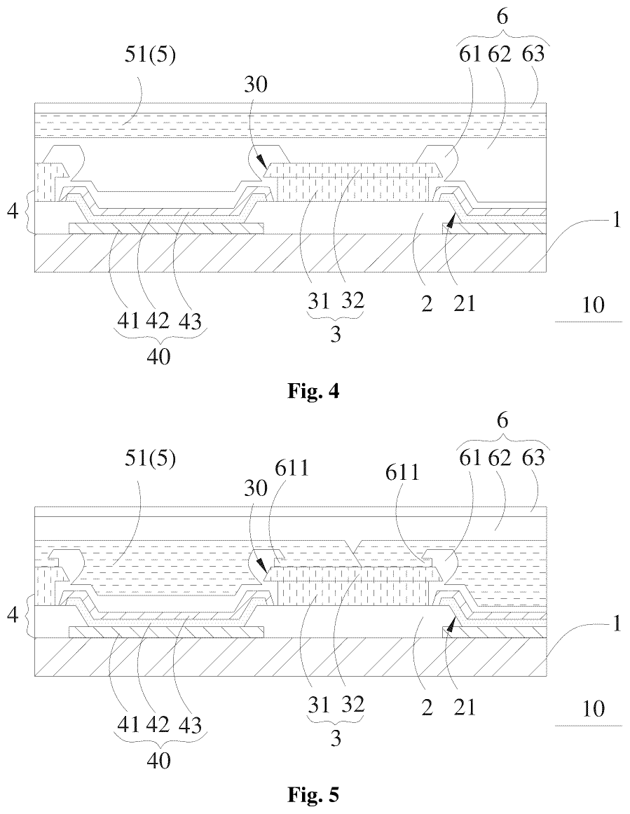

Specifically, the light filtering layer 5 is arranged between the first encapsulation layer 61 and the second encapsulation layer 62 as shown in FIG. 3 or between the second encapsulation layer 62 and the third encapsulation layer 63 as shown in FIG. 4.

In the above implementation, the first encapsulation layers 61 are arranged at intervals in the isolation structure 3 during the formation process. That is, on a side of the isolation structure 3 away from the array base plate 1, there may a space D between the first encapsulation layers 61 corresponding to the adjacent light-emitting units 40, and the first encapsulation layers 61 and the light-emitting units 40 are in a one-to-one correspondence, so that independent encapsulation of the light-emitting units 40 can be achieved. At the same time, the light filtering functional portion 51 is located within the space D, that is, adjacent light filtering functional portions 51 fill the spaces D, so as to facilitate the subsequent forming of the second encapsulation layer 62 and the third encapsulation layer 63.

In a feasible implementation, the first encapsulation layer 61 is in contact with a side of the light-emitting unit 40 away from the array base plate and covers a side wall of the isolation structure 3, the first encapsulation layer 61 further extends to a side surface of the isolation structure 3 away from the array base plate 1 and forms a gap 611 with the side surface of the isolation structure 3 away from the array base plate 1, and the light filtering layer 5 is partially located in the gap 611.

In the above implementation, the first encapsulation layer 61 extends to the side surface of the isolation structure 3 away from the array base plate 1 during the manufacturing process, and due to the limitation of the manufacturing process, the first encapsulation layer 61 forms the gap 611 with the side surface of the isolation structure 3 away from the array base plate, and the light filtering layer 5 is partially located in the gap 611, so that the gap 611 may be filled, and an encapsulation effect of the first encapsulation layer 61 on the light-emitting unit 40 is improved while fixing strength of the edge of the first encapsulation layer 61 can be increased, thereby further improving the encapsulation effect. In a feasible implementation, as shown in FIG. 3, materials of the first encapsulation layer 61 and the third encapsulation layer 63 are inorganic materials, a material of the second encapsulation layer 62 is an organic material, and the light filtering layer 5 is arranged between the first encapsulation layer 61 and the second encapsulation layer 62.

In the above implementation, the inorganic materials are used in the first encapsulation layer 61 and the third encapsulation layer 63, and the inorganic materials have a strong ability to isolate water and oxygen. The organic material is used in the second encapsulation layer 62, and the organic material is highly flexible and has strong flatness. By arranging the light filtering layer 5 between the first encapsulation layer 61 and the second encapsulation layer 62, on the one hand, the light filtering layer 5 is arranged on a side of the first encapsulation layer 61 away from the light-emitting unit 40, so that the first encapsulation layer 61 is in direct contact with the light-emitting unit 40, which can ensure that the encapsulation effect of the first encapsulation layer 61 on the light-emitting unit 40 is not interfered by the light filtering layer 5. On the other hand, the second encapsulation layer 62 is arranged on a side of the light filtering layer 5 away from the array base plate 1, and a side surface of the of the light filtering layer 5 away from the array base plate can be flattened through the second encapsulation layer 62, so as to improve a contact effect of the second encapsulation layer 62 with the third encapsulation layer 63, which is helpful to improve an encapsulation effect of the third encapsulation layer 63.

Meanwhile, the light filtering layer 5 is arranged in the encapsulation layer 6, so that a distance between the light filtering layer 5 and the pixel opening 21 of the pixel definition layer 2 is reduced. This facilitates the alignment of the light filtering functional portion 51 with the light-emitting unit 40 located in the pixel opening 21, and thus the accuracy of aligning the light filtering functional portion 51 with the light-emitting unit 40 is higher.

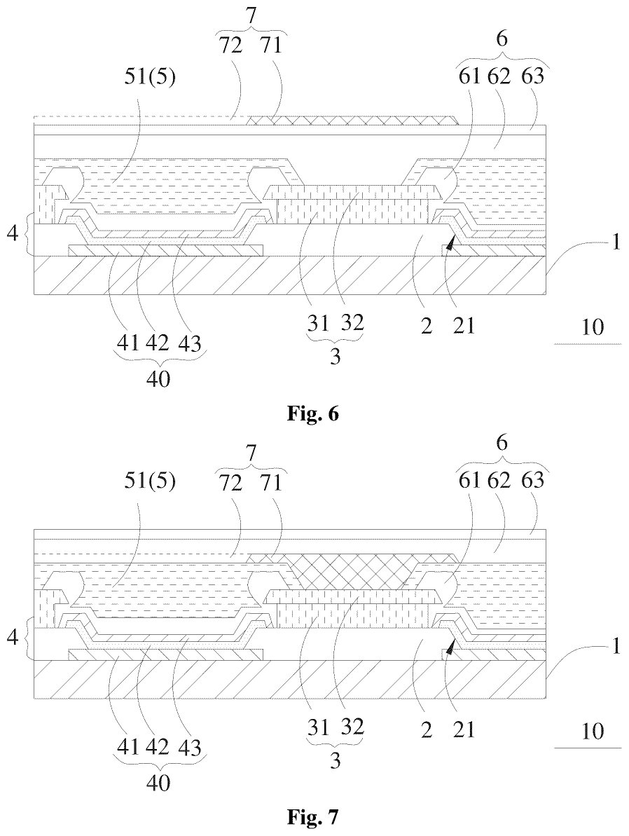

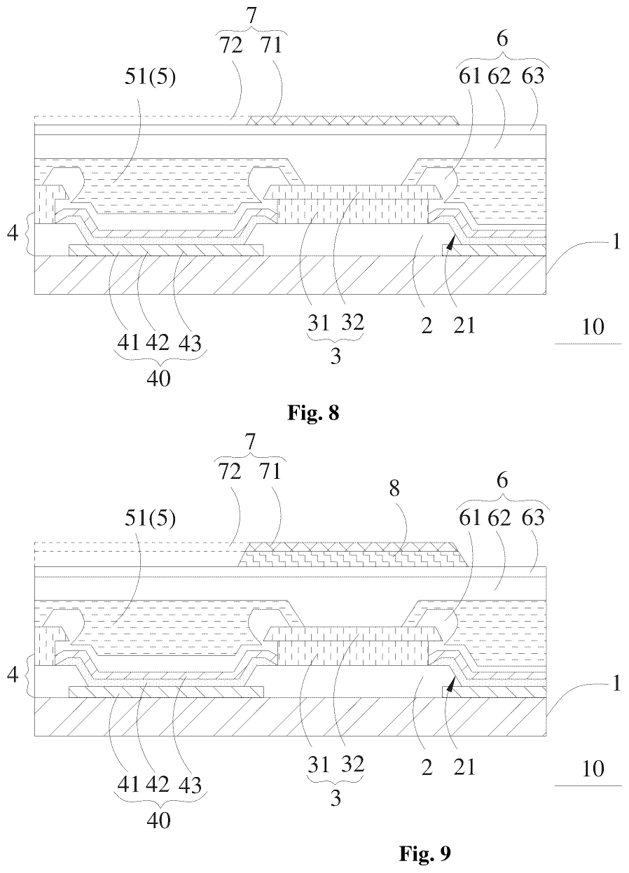

In a feasible implementation, as shown in FIG. 6, FIG. 7, and FIG. 8, the display panel 10 according to the present application further includes a first light blocking layer 7 including a first body portion 71 and a first aperture 72, the first aperture 72 is arranged opposite to the isolation opening 30, the first light blocking layer 7 is arranged within the encapsulation layer 6, or the first light blocking layer 7 is arranged on a side of the encapsulation layer 6 away from the array base plate 1.

In the display panel as shown in FIG. 6, the first light blocking layer 7 is arranged on a side of the encapsulation layer 6 away from the array base plate 1, and light is absorbed by the first body portion 71 in the first light blocking layer 7, so that the reflectivity of the display panel can be reduced.

In the display panel as shown in FIG. 7, the first light blocking layer 7 is arranged in the encapsulation layer 6, and the first body portion 71 and the light filtering functional portion 51 are arranged on the same layer, so that the alignment accuracy when the first body portion 71 is arranged can be increased. Therefore, the first body portion 71 well exposes the pixel opening while effectively blocking the isolation structure 3, and the light-emitting amount of the light-emitting unit is ensured and the probability of optical crosstalk between adjacent light-emitting units is reduced while the reflectivity of the display panel is reduced. In the display panel as shown in FIG. 8, the light filtering functional portion 51 covers the isolation structure 3, the first light blocking layer 7 is arranged on a side of the encapsulation layer 6 away from the array base plate 1, and light is absorbed by the first body portion 71 in the first light blocking layer 7, so that the reflectivity of the display panel 10 can be reduced.

In the above implementation, by arranging the first light blocking layer 7, the mutual crosstalk between the adjacent light-emitting units 40 can be further reduced while the light entering the display panel 10 can be absorbed by the first body portion 71, and the amount of the external light entering a side of the first light blocking layer 7 close to the array base plate 1 can be reduced, so that the amount of the light reflected by the internal structure of the display panel 10 (for example, the amount of the external light reflected by the isolation structure 3) can be reduced, so as to further reduce the reflectivity of the display panel 10 and increase the contrast of the display panel 10.

In a feasible implementation, as shown in FIG. 9, the display panel 10 according to the present application further includes a touch layer 8, and the light filtering layer 5 may be arranged on a side of the touch layer 8 close to the array base plate 1. Meanwhile, the distance between the light filtering layer 5 and the pixel opening 21 is relatively small, and the accuracy of aligning the light filtering functional portion 51 with the light-emitting unit 40 can be increased.

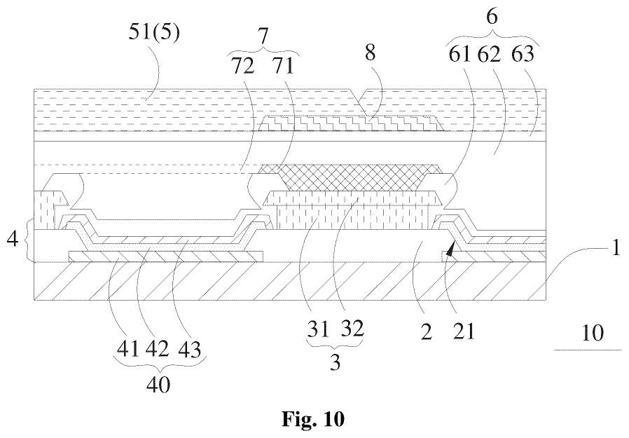

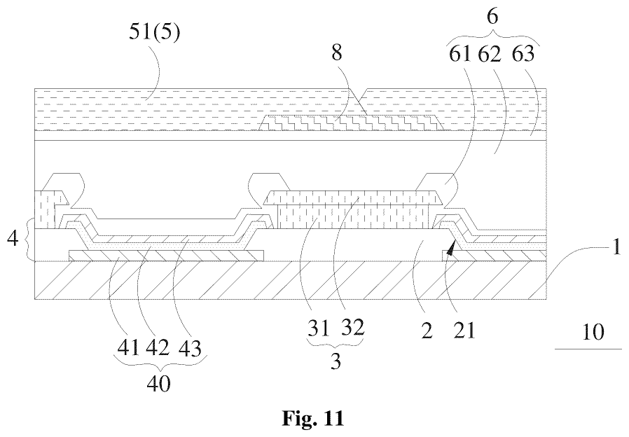

In another feasible implementation, as shown in FIG. 10 and FIG. 11, the display panel 10 according to the present application further includes a touch layer 8, and the light filtering layer 5 is arranged on a side of the touch layer 8 away from the array base plate 1. The manufacturing process is simple. Under this condition, as shown in FIG. 10, the first light blocking layer 7 may be arranged, so as to reduce the reflectivity of the isolation structure in the display panel. Or, as shown in FIG. 11, the first light blocking layer 7 may be omitted, so as to save manufacturing cost.

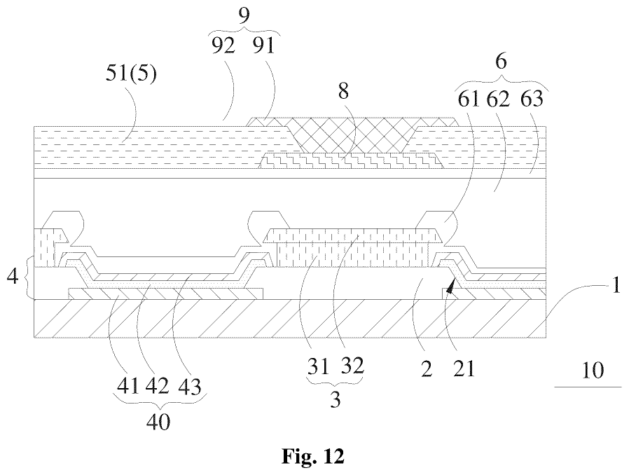

In a feasible implementation, as shown in FIG. 12, the display panel 10 according to the present application further includes a second light blocking layer 9 arranged on a side of the touch layer 8 away from the array base plate 1, the second light blocking layer 9 includes a second body portion 91 and a second aperture 92, the second aperture 92 is arranged opposite to the isolation opening 30, and an orthographic projection of the second body portion 91 on the array base plate 1 covers an orthographic projection of the isolation structure 3 on the array base plate 1.

In the above implementation, the touch layer 8 includes a metal layer, and the metal layer easily reflect the light entering a side of the metal layer away from the array base plate 1, the second aperture 92 in the second light blocking layer 9 can expose the light-emitting unit 40, and the second light blocking layer 9 can block a position of the touch layer 8 opposite to the isolation structure 3, so as to block a part of the metal layer opposite to the isolation structure 3. The second light blocking layer 9 can absorb the external light to reduce the probability that the light enters the part of the metal layer opposite to the isolation structure 3, thereby reducing the reflectivity of the display panel 10 and increasing the contrast of the display panel 10 while ensuring the display effect.

Specifically, as shown in FIG. 12, under a condition that the second light blocking layer 9 is arranged, the first light blocking layer 7 may be omitted to reduce manufacturing cost.

Either the first light blocking layer 7 or the second light blocking layer 9 in the present application may be arranged, and the specific arrangements may be selected according to actual requirements, which is not particularly limited in the present application.

In a feasible implementation, as shown in FIG. 4, the present application provides another display panel 10 including an array base plate 1, an isolation structure 3, a light-emitting layer 4, an encapsulation layer 6, and a light filtering layer 5. The isolation structure 3 is formed on a side of the array base plate 1 and defines a plurality of isolation openings 21; the light-emitting layer 4 includes a plurality of light-emitting units 40, and the light-emitting unit 40 is arranged in the isolation opening 21 and includes a first electrode 41, a light-emitting functional layer 42, and a second electrode 43, the first electrode 41 is formed on a side of the array base plate 1, the light-emitting functional layer 42 is formed on a side of the first electrode 41 away from the array base plate 1, the second electrode 43 is formed on one side of the light-emitting functional layer 42 away from the array base plate 1, and adjacent light-emitting units 40 are independent from each other; the encapsulation layer 6 is formed on a side of the light-emitting layer 4 away from the array base plate 1, and the encapsulation layer 6 includes a first encapsulation layer 61, a second encapsulation layer 62, and a third encapsulation layer 63 stacked along a direction away from the array base plate; the light filtering layer 5 is formed between the first encapsulation layer 61 and the second encapsulation layer 62 and includes light filtering functional portions 51, and the light filtering functional portion 51 extends to a side of the isolation structure 3 away from the array base plate.

The present application provides the display panel 10 including the array base plate 1, the isolation structure 3, the light-emitting layer 4, the encapsulation layer 6, and the light filtering layer 5. The encapsulation layer 6 is formed on a side of the light-emitting layer 4 away from the array base plate 1, and the encapsulation layer 6 includes the first encapsulation layer 61, the second encapsulation layer 62, and the third encapsulation layer 63 stacked along the direction away from the array base plate; the light filtering layer 5 is formed between the first encapsulation layer 61 and the second encapsulation layer 62 and includes the light filtering functional portions 51, and the light filtering functional portion 51 is located on a side of the light-emitting unit 40 away from the array base plate 1 and corresponds to the light-emitting unit 40. The light filtering functional portion 51 can filter the light entering the display panel 10 from the outside, so that the amount of the light entering the display panel is reduced, the amount of the light reflected by the internal structure of the display panel 10 when the light enters the display panel 10 is reduced, and thus the diverged amount of the light reflected by the internal structure of the display panel 10 can be reduced, thereby increasing the contrast of the display panel 10. Specifically, the orthographic projection of the light filtering functional portion 51 on the array base plate 1 covers at least a part of the orthographic projection of the isolation structure 3 on the array base plate 1, so that the amount of the external light entering a side surface of the isolation structure 3 away from the array base plate 1 is reduced by covering the isolation structure 3 with the light filtering functional portions 51. The light towards the isolation structure 3 first enters a part of the light filtering functional portion 51 opposite to the isolation structure 3, light of a color different from a color of the light filtering functional portion 51 is filtered out by the light filtering functional portion 51, and the light entering the light filtering functional portion 51 is refracted or scattered, so that the amount of the light entering the side surface of the isolation structure 3 away from the array base plate 1 is reduced greatly, thereby reducing the amount of the light reflected by the isolation structure 3, which is helpful to increase the contrast of the display panel 10. Meanwhile, the light transmittance of the light filtering layer 5 is high, so that the light-emitting rate of the display panel 10 can be ensured while the contrast of the display panel 10 is increased, thereby ensuring low power consumption of the display panel 10. Meanwhile, since the light filtering layer 5 is formed between the first encapsulation layer 61 and the second encapsulation layer 62, on the one hand, the light filtering layer 5 is arranged on a side of the first encapsulation layer 61 away from the light-emitting unit 40, so that the first encapsulation layer 61 is in direct contact with the light-emitting unit 40, which can ensure that the encapsulation effect of the first encapsulation layer 61 on the light-emitting unit 40 is not interfered by the light filtering layer 5. On the other hand, the second encapsulation layer 62 is arranged on a side of the light filtering layer 5 away from the array base plate 1, and the side surface of the of the light filtering layer 5 away from the array base plate can be flattened through the second encapsulation layer 62, so as to improve the contact effect of the second encapsulation layer 62 with the third encapsulation layer 63, which is helpful to improve the encapsulation effect of the third encapsulation layer 63.

Meanwhile, the light filtering layer 5 is arranged in the encapsulation layer 6, so that the distance between the light filtering layer 5 and the pixel opening 21 of the pixel definition layer 2 is reduced. This facilitates the alignment of the light filtering functional portion 51 with the light-emitting unit 40 located in the pixel opening 21, and thus the accuracy of aligning the light filtering functional portion 51 with the light-emitting unit 40 is higher.

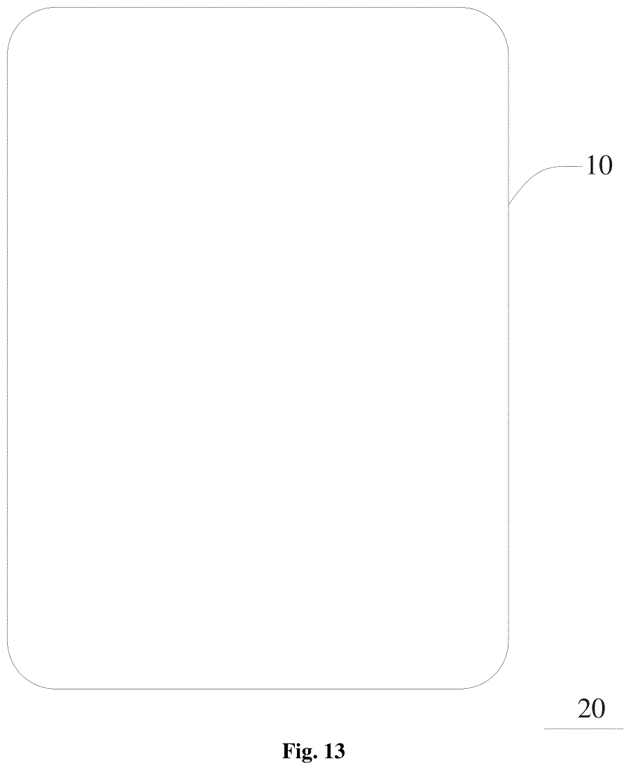

The present application further provides a display apparatus 20, as shown in FIG. 13, and the display apparatus 20 includes any of the display panels 10 according to the above implementations of the present application.

The display apparatus 20 has low power consumption, low cost, and high contrast. That is, the display apparatus 20 has a good overall performance, so that a using effect of the display device 20 can be improved.

The display apparatus 20 may be a mobile terminal such as a mobile phone and a notebook computer, or a fixed terminal such as a television and a computer display, or may be a wearable device such as a watch, which is not particularly limited in the present application.

The above embodiments of the present application do not exhaustively describe all the details and do not limit the invention to only the specific embodiments. Obviously, many modifications and variations can be made based on the above description. These embodiments are selected and specifically described in the description to better explain the principles and practical applications of the present application, so that those skilled in the art can make good use of the present application and make modifications based on the present application. The present application is limited only by the claims, along with their full scope and equivalents.

1-20. (canceled)

21. A display panel, comprising:
an array base plate;
an isolation structure formed on a side of the array base plate and defining a plurality of isolation openings;
a light-emitting layer comprising a plurality of light-emitting units arranged at intervals, wherein the light-emitting unit is arranged in the isolation opening and comprises a first electrode, a light-emitting functional layer, and a second electrode, the first electrode is formed on a side of the array base plate, the light-emitting functional layer is formed on a side of the first electrode away from the array base plate, the second electrode is formed on a side of the light-emitting functional layer away from the array base plate, and adjacent light-emitting units are independent from each other; and
a light filtering layer formed on a side of the light-emitting layer away from the array base plate and comprising light filtering functional portions, wherein the light filtering functional portion is located on a side of the light-emitting unit away from the array base plate and extends to a side of the isolation structure away from the array base plate.

22. The display panel according to claim 21, wherein an orthographic projection of the light filtering functional portion on the array base plate covers an orthographic projection of the light-emitting unit on the array base plate.

23. The display panel according to claim 21, wherein the isolation structure comprises a first layer and a second layer stacked along a direction away from the array base plate, and an orthographic projection of the first layer on the array base plate is within an orthographic projection of the second layer on the array base plate.

24. The display panel according to claim 21, wherein the display panel further comprises a pixel definition layer formed on a side of the array base plate and comprising a plurality of pixel openings, an orthographic projection of the pixel opening on the array base plate coincides with an orthographic projection of the isolation opening on the array base plate, the isolation structure is located on a side of the pixel definition layer away from the array base plate, and an orthographic projection of the isolation structure on the pixel definition layer is located between adjacent pixel openings.

25. The display panel according to claim 24, wherein a material of the pixel definition layer is an inorganic material.

26. The display panel according to claim 21, wherein the isolation structure is arranged on a side surface of the array base plate.

27. The display panel according to claim 21, wherein an orthographic projection of the light filtering functional portion on the array base plate covers at least a part of an orthographic projection of the isolation structure on the array base plate.

28. The display panel according to claim 27, wherein the isolation structure comprises a first layer and a second layer stacked along a direction away from the array base plate, an orthographic projection of the first layer on the array base plate is located within an orthographic projection of the second layer on the array base plate, orthographic projections of adjacent light filtering functional portions on the array base plate are overlapped to form an overlapped region, and an orthographic projection of the overlapped region on the array base plate covers a part of the orthographic projection of the second layer on the array base plate.

29. The display panel according to claim 27, wherein orthographic projections of adjacent light filtering functional portions on the array base plate are overlapped to form an overlapped region, and an orthographic projection of the overlapped region on the array base plate covers an orthographic projection of a center of the isolation structure along an arrangement direction of the adjacent light filtering functional portions on the array base plate.

30. The display panel according to claim 27, wherein the orthographic projection of the light filtering functional portion on the array base plate covers the orthographic projection of the isolation structure on the array base plate, and orthographic projections of adjacent light filtering functional portions on the array base plate are staggered.

31. The display panel according to claim 21, further comprising at least one encapsulation layer formed on a side of the light-emitting layer away from the array base plate, wherein the encapsulation layer comprises a first encapsulation layer, a second encapsulation layer, and a third encapsulation layer stacked along a direction away from the array base plate, and the light filtering layer is arranged between the first encapsulation layer and the second encapsulation layer or between the second encapsulation layer and the third encapsulation layer.

32. The display panel according to claim 21, further comprising at least one encapsulation layer formed on a side of the light-emitting layer away from the array base plate, wherein the encapsulation layer comprises a first encapsulation layer, a second encapsulation layer, and a third encapsulation layer stacked along a direction away from the array base plate, and the light filtering layer is arranged on a side of the encapsulation layer away from the array base plate and adjacent to the encapsulation layer.

33. The display panel according to claim 31, wherein materials of the first encapsulation layer and the third encapsulation layer are inorganic materials, a material of the second encapsulation layer is an organic material, and the light filtering layer is arranged between the first encapsulation layer and the second encapsulation layer.

34. The display panel according to claim 31, wherein the at least one encapsulation layer comprises a plurality of encapsulation layers, the first encapsulation layers of the plurality of encapsulation layers are arranged at intervals at the isolation structure, and the first encapsulation layers and the light-emitting units are in a one-to-one correspondence; and
the first encapsulation layer is in contact with a side of the light-emitting unit away from the array base plate and covers a side wall of the isolation structure, the first encapsulation layer extends to a side surface of the isolation structure away from the array base plate and forms a gap with the side surface of the isolation structure away from the array base plate, and the light filtering layer is partially located in the gap.

35. The display panel according to claim 31, further comprising a first light blocking layer comprising a first body portion and a first aperture, wherein the first aperture is arranged opposite to the isolation opening, the first light blocking layer is arranged between the first encapsulation layer and the second encapsulation layer or between the second encapsulation layer and the third encapsulation layer, or the first light blocking layer is arranged on a side of the encapsulation layer away from the array base plate.

36. The display panel according to claim 31, further comprising a touch layer, wherein the light filtering layer is arranged on a side of the touch layer close to the array base plate.

37. The display panel according to claim 36, further comprising a second light blocking layer arranged on a side of the touch layer away from the array base plate, wherein the second light blocking layer comprises a second body portion and a second aperture, the second aperture is arranged opposite to the isolation opening, and an orthographic projection of the second body portion on the array base plate covers an orthographic projection of the isolation structure on the array base plate.

38. The display panel according to claim 21, wherein a material of the isolation structure is metal.

39. A display panel, comprising:
an array base plate;
an isolation structure formed on a side of the array base plate and defining a plurality of isolation openings;
a light-emitting layer comprising a plurality of light-emitting units arranged at intervals, wherein the light-emitting unit is arranged in the isolation opening and comprises a first electrode, a light-emitting functional layer, and a second electrode, the first electrode is formed on a side of the array base plate, the light-emitting functional layer is formed on a side of the first electrode away from the array base plate, the second electrode is formed on a side of the light-emitting functional layer away from the array base plate, and adjacent light-emitting units are independent from each other;
an encapsulation layer formed on a side of the light-emitting layer away from the array base plate, wherein the encapsulation layer comprises a first encapsulation layer, a second encapsulation layer, and a third encapsulation layer stacked along a direction away from the array base plate; and
a light filtering layer formed between the first encapsulation layer and the second encapsulation layer and comprising light filtering functional portions, wherein the light filtering functional portion extends to a side of the isolation structure away from the array base plate.

40. A display apparatus, comprising the display panel according to claim 21.
